(19) United States
(12) Patent Application Publication
(10) Pub. No.: US 2026/0101428 A1
(43) Pub. Date: Apr. 9, 2026

(54) EXTREME ULTRAVIOLET LIGHT GENERATION APPARATUS AND ELECTRONIC DEVICE MANUFACTURING METHOD

(71) Applicant: Gigaphoton Inc., Oyama-shi (JP)

(72) Inventor: Yoshiyuki HONDA, Oyama-shi (JP)

(73) Assignee: Gigaphoton Inc., Oyama-shi (JP)

(21) Appl. No.: 19/320,442

(22) Filed: Sep. 5, 2025

(30) Foreign Application Priority Data
Oct. 8, 2024 (JP) 2024-176543

(51) Int. Cl. H05G 2/00; G01N 21/88; G01N 21/956; G03F 1/22; G03F 7/00

(52) U.S. Cl. CPC H05G 2/009; G01N 21/8806; G01N 21/956; G03F 1/22; G03F 7/70033; H05G 2/0025; G01N 2021/95676; G01N 2201/061

(57) ABSTRACT

An extreme ultraviolet light generation apparatus includes a chamber surrounding a first space, a partition wall surrounding a second space and including a first opening allowing the first space to communicate with the second space, a target supply unit configured to supply a target including a target substance to a plasma generation region in the second space, an EUV light concentrating mirror configured to concentrate extreme ultraviolet light generated in the plasma generation region, a target collection unit configured to collect the target that has passed through the plasma generation region and adhesion debris of the target substance that has adhered to an inner surface of the partition wall, a temperature adjuster configured to heat the partition wall, and a first switch configured to switch opening and closing of the first opening.

### CROSS-REFERENCE TO RELATED APPLICATIONS

The present application claims the benefit of Japanese Patent Application No. 2024-176543, filed on Oct. 8, 2024, the entire contents of which are hereby incorporated by reference.

### BACKGROUND

### 1. Technical Field

The present disclosure relates to an extreme ultraviolet light generation apparatus and an electronic device manufacturing method.

2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, it is expected to develop a semiconductor exposure apparatus that combines an apparatus for generating extreme ultraviolet (EUV) light having a wavelength of about 13 nm with a reduced projection reflection optical system.

As the EUV light generation apparatus, a laser produced plasma (LPP) type apparatus using plasma generated by irradiating a target substance with pulse laser light has been developed.

### LIST OF DOCUMENTS

### Patent Documents

Patent Document 1: U.S. Patent Application Publication No. 2022/082927

Patent Document 2: Japanese Patent Application Publication No. 2009-026935

### SUMMARY

An extreme ultraviolet light generation apparatus according to an aspect of the present disclosure includes a chamber surrounding a first space, a partition wall surrounding a second space and including a first opening allowing the first space to communicate with the second space, a target supply unit configured to supply a target including a target substance to a plasma generation region in the second space, an EUV light concentrating mirror configured to concentrate extreme ultraviolet light generated in the plasma generation region, a target collection unit configured to collect the target that has passed through the plasma generation region and adhesion debris of the target substance that has adhered to an inner surface of the partition wall, a temperature adjuster configured to heat the partition wall, and a first switch configured to switch opening and closing of the first opening.

An electronic device manufacturing method according to an aspect of the present disclosure includes generating extreme ultraviolet light using an extreme ultraviolet light generation apparatus, outputting the extreme ultraviolet light to an exposure apparatus, and exposing a photosensitive substrate to the extreme ultraviolet light in the exposure apparatus to manufacture an electronic device. Here, the extreme ultraviolet light generation apparatus includes a chamber surrounding a first space, a partition wall surrounding a second space and including a first opening allowing the first space to communicate with the second space, a target supply unit configured to supply a target including a target substance to a plasma generation region in the second space, an EUV light concentrating mirror configured to concentrate the extreme ultraviolet light generated in the plasma generation region, a target collection unit configured to collect the target that has passed through the plasma generation region and adhesion debris of the target substance that has adhered to an inner surface of the partition wall, a temperature adjuster configured to heat the partition wall, and a first switch configured to switch opening and closing of the first opening.

An electronic device manufacturing method according to an aspect of the present disclosure includes inspecting a defect of a mask by irradiating the mask in an inspection apparatus with extreme ultraviolet light generated by an extreme ultraviolet light generation apparatus, selecting a mask using a result of the inspection, and exposing and transferring a pattern formed on the selected mask onto a photosensitive substrate. Here, the extreme ultraviolet light generation apparatus includes a chamber surrounding a first space, a partition wall surrounding a second space and including a first opening allowing the first space to communicate with the second space, a target supply unit configured to supply a target including a target substance to a plasma generation region in the second space, an EUV light concentrating mirror configured to concentrate the extreme ultraviolet light generated in the plasma generation region, a target collection unit configured to collect the target that has passed through the plasma generation region and adhesion debris of the target substance that has adhered to an inner surface of the partition wall, a temperature adjuster configured to heat the partition wall, and a first switch configured to switch opening and closing of the first opening.

### BRIEF DESCRIPTION OF THE DRAWINGS

Embodiments of the present disclosure will be described below merely as examples with reference to the accompanying drawings.

FIG. 1 shows the configuration of an LPP EUV light generation system.

FIG. 2 shows the configuration of the EUV light generation system according to a comparative example.

FIG. 3 shows the configuration of an EUV light generation apparatus shown in FIG. 2.

FIG. 4 shows the configuration of the EUV light generation system according to a first embodiment.

FIG. 5 shows the configuration of the EUV light generation apparatus shown in FIG. 4.

FIG. 6 shows the configuration of the EUV light generation system according to a first modification of the first embodiment.

FIG. 7 shows the configuration of the EUV light generation apparatus shown in FIG. 6.

FIG. 8 shows the configuration of the EUV light generation system according to a second modification of the first embodiment.

FIG. 9 shows the configuration of the EUV light generation apparatus shown in FIG. 8.

FIG. 10 shows the configuration of the EUV light generation apparatus according to a second embodiment.

FIG. 11 shows the configuration of the EUV light generation apparatus according to a third embodiment.

FIG. 12 shows the configuration of an exposure apparatus connected to the EUV light generation system.

FIG. 13 shows the configuration of an inspection apparatus connected to the EUV light generation system.

### DESCRIPTION OF EMBODIMENTS

### Contents

1. Overall description of EUV light generation system 11
   1.1 Configuration
   1.2 Operation
2. Comparative example
   2.1 Configuration
   2.2 Operation
   2.3 Problem of comparative example
3. EUV light generation apparatus 1b in which partition wall 37b includes heater
   3.1 Configuration
   3.2 Operation
   3.3 Effect
4. EUV light generation apparatus 1c including shutter 35c instead of gate valve 35b
   4.1 Configuration and operation
   4.2 Effect
5. EUV light generation apparatus 1d in which gate valve 35d includes heater
   5.1 Configuration and operation
   5.2 Effect
6. EUV light generation apparatus 1e in which gate valve 36e is arranged at target passage port 373
   6.1 Configuration and operation
   6.2 Effect
7. EUV light generation apparatus 1f in which gate valve 36e is arranged at target passage port 373 and gate valve 35f is arranged at EUV light passage port 372
   7.1 Configuration and operation
   7.2 Effect
8. Others
   8.1 Example of EUV light utilization apparatus 6
   8.2 Supplement

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

1. Overall description of EUV light generation system 11
1.1 Configuration

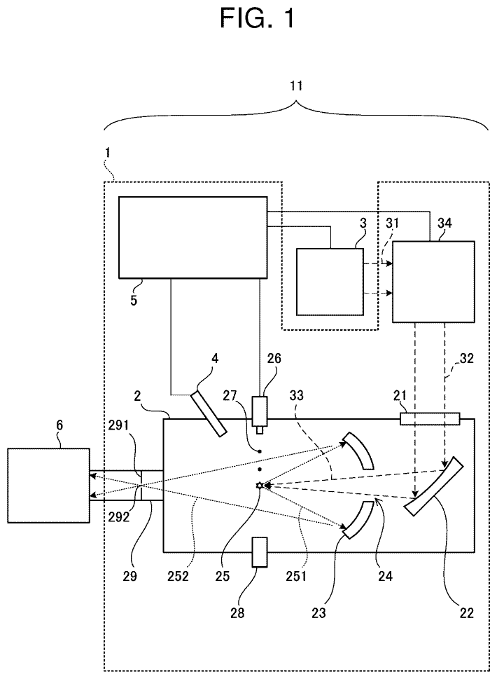

FIG. 1 shows the configuration of an LPP EUV light generation system 11. An EUV light generation apparatus 1 is used together with a laser device 3. In the present disclosure, a system including the EUV light generation apparatus 1 and the laser device 3 is referred to as the EUV light generation system 11. The EUV light generation apparatus 1 includes a chamber 2 and a target supply unit 26. The chamber 2 is a sealable container. The target supply unit 26 supplies a target 27 containing a target substance into the chamber 2. The material of the target substance may include tin, terbium, gadolinium, lithium, xenon, or a combination of any two or more thereof.

A through hole is formed in a wall of the chamber 2. The through hole is blocked by a window 21 and pulse laser light 32 output from the laser device 3 is transmitted through the window 21. An EUV light concentrating mirror 23 having a spheroidal reflection surface is arranged in the chamber 2. The EUV light concentrating mirror 23 has first and second focal points. A multilayer reflection film in which molybdenum and silicon are alternately stacked is formed on a surface of the EUV light concentrating mirror 23. The EUV light concentrating mirror 23 is arranged such that the first focal point is located in a plasma generation region 25 and the second focal point is located at an intermediate focal point 292. A through hole 24 is formed at the center of the EUV light concentrating mirror 23, and pulse laser light 33 passes through the through hole 24.

The EUV light generation apparatus 1 includes a processor 5, a target sensor 4, and the like. The target sensor 4 detects at least one of the presence, trajectory, position, and velocity of the target 27. The target sensor 4 may have an imaging function.

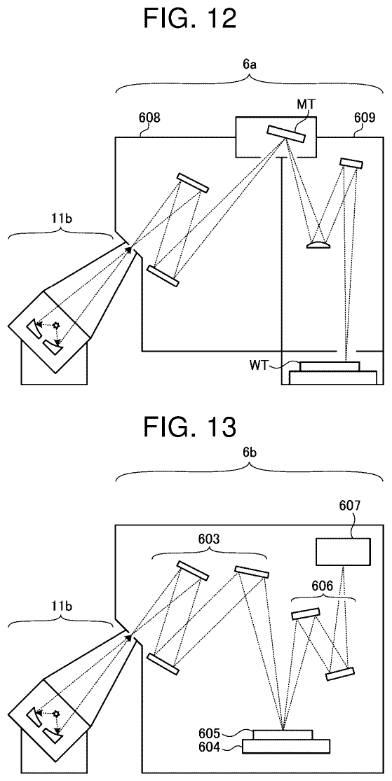

Further, the EUV light generation apparatus 1 includes a connection portion 29 providing communication between the internal space of the chamber 2 and the internal space of an EUV light utilization apparatus 6. The EUV light utilization apparatus 6 may be an exposure apparatus 6a shown in FIG. 12 or an inspection apparatus 6b shown in FIG. 13. A wall 291 in which an aperture is formed is arranged in the connection portion 29. The wall 291 is arranged such that the aperture is located at the second focal point of the EUV light concentrating mirror 23.

Further, the EUV light generation apparatus 1 includes a laser light transmission device 34, a laser light concentrating mirror 22, a target collection unit 28 for collecting the target 27, and the like. The laser light transmission device 34 includes an optical element for defining a transmission state of the pulse laser light 32, and an actuator for adjusting the position, posture, and the like of the optical element.
1.2 Operation

Operation of the EUV light generation system 11 will be described with reference to FIG. 1. Pulse laser light 31 output from the laser device 3 enters, via the laser light transmission device 34, the chamber 2 through the window 21 as the pulse laser light 32. The pulse laser light 32 travels along a laser light path in the chamber 2, is reflected by the laser light concentrating mirror 22, and is radiated to the target 27 as the pulse laser light 33.

The target supply unit 26 outputs the target 27 toward the plasma generation region 25 in the chamber 2. The target 27 is irradiated with the pulse laser light 33. The target 27 irradiated with the pulse laser light 33 is turned into plasma, and radiation light 251 is radiated from the plasma. EUV light contained in the radiation light 251 is reflected by the EUV light concentrating mirror 23 with higher reflectance than light in other wavelength ranges. Reflection light 252 including the EUV light reflected by the EUV light concentrating mirror 23 is concentrated at the intermediate focal point 292 and output to the EUV light utilization apparatus 6.

One target 27 may be irradiated with a plurality of pulses included in the pulse laser light 33. In this case, for example, the laser device 3 includes a prepulse laser (not shown) and a main pulse laser (not shown). Prepulse laser light output from the prepulse laser has a lower energy than main pulse laser light output from the main pulse laser. The target 27 is diffused by irradiation with the prepulse laser light. The diffused target 27 is turned into plasma by irradiation with the main pulse laser light.

The processor 5 controls the entire EUV light generation system 11. The processor 5 processes a detection result of the target sensor 4. Based on the detection result of the target sensor 4, the processor 5 controls the timing at which the target 27 is output, the output direction of the target 27, and the like. Further, the processor 5 controls oscillation timing of the laser device 3, a travel direction of the pulse laser light 32, the concentration position of the pulse laser light 33, and the like. The above-described various kinds of control are merely examples, and other control may be added as necessary.

### 2. Comparative Example

2.1 Configuration

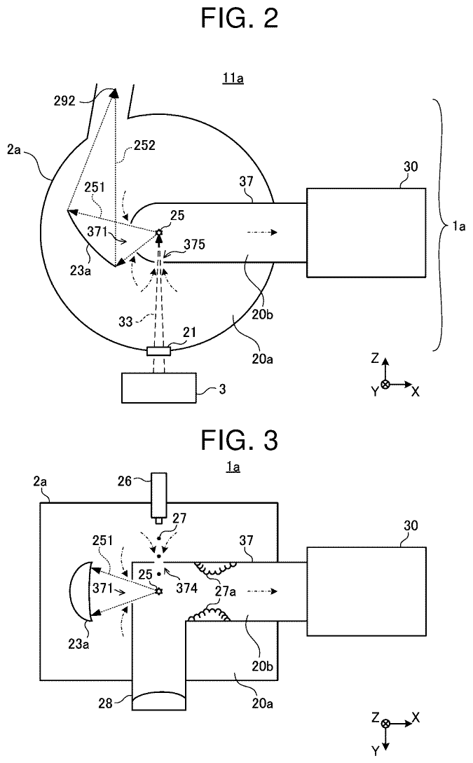

FIG. 2 shows the configuration of an EUV light generation system 11a according to a comparative example, and FIG. 3 shows the configuration of an EUV light generation apparatus 1a shown in FIG. 2. The comparative example of the present disclosure is an example recognized by the applicant as known only by the applicant, and is not a publicly known example admitted by the applicant. In FIGS. 2 and 3, the X direction, the Y direction, and the Z direction perpendicular to each other are shown. FIG. 2 is a view of the EUV light generation system 11a viewed in the Y direction, and FIG. 3 is a view of the EUV light generation apparatus 1a viewed in the Z direction. The Y direction is the direction of gravity, and the Z direction is the incident direction of the pulse laser light 33 toward the plasma generation region 25. The EUV light generation apparatus 1a includes a chamber 2a and a partition wall 37.

The chamber 2a has a substantially cylindrical shape surrounding a first space 20a. The center axis of the cylindrical shape is parallel to the Y direction, and a target supply unit 26 and a target collection unit 28 are arranged at positions on the center axis. The target collection unit 28 has a substantially cylindrical shape, and the center axis of the cylindrical shape is parallel to the Y direction. The plasma generation region 25 is located between the target supply unit 26 and the target collection unit 28.

The partition wall 37 includes a part having a substantially cylindrical shape surrounding a second space 20b, and penetrates the side surface of the chamber 2a. The center axis of the cylindrical shape is parallel to the X direction, and the plasma generation region 25 is located at a position on the center axis. A part of the partition wall 37 is located inside the chamber 2a, covers the plasma generation region 25, and is connected to the target collection unit 28. Another part of the partition wall 37 is located outside the chamber 2a and is connected to an exhaust device 30. Stainless steel or molybdenum is used as the material of the partition wall 37.

In the chamber 2a, the partition wall 37 has a plurality of through holes that allow the first space 20a to communicate with the second space 20b. The plurality of through holes include an EUV light passage port 371, a target passage port 374, a laser light passage port 375, and a through hole (not shown) for a sensor (not shown). The EUV light passage port 371 is an example of the first opening in the present disclosure.

A gas supply device (not shown) for supplying a gas to the first space 20a is connected to the chamber 2a. The gas to be supplied is, for example, a hydrogen gas.

The EUV light concentrating mirror 23a is arranged at a position inside the first space 20a and outside the second space 20b. The EUV light passage port 371 is located on the optical path of the radiation light 251 generated at the plasma generation region 25 and directed toward the EUV light concentrating mirror 23a. The EUV light concentrating mirror 23a is arranged such that the center axis of the optical path of the reflection light 252 is inclined with respect to the center axis of the optical path of the radiation light 251.
2.2 Operation

The pulse laser light 33 output from the laser device 3 passes through the window 21 and the laser light passage port 375, and is guided to the plasma generation region 25.

The target 27 output from the target supply unit 26 located outside the second space 20b passes through the target passage port 374 and is supplied to the plasma generation region 25. Among the plurality of targets 27, the targets 27 without being irradiated with the pulse laser light 33 and without being turned into plasma pass through the plasma generation region 25, and reach the target collection unit 28.

The target 27 irradiated with the pulse laser light 33 is turned into plasma, and the radiation light 251 is radiated from the plasma. The EUV light concentrating mirror 23a reflects the radiation light 251 that has passed through the EUV light passage port 371, and concentrates the reflection light 252 including the EUV light at the intermediate focal point 292.

The exhaust device 30 exhausts the gas in the second space 20b to the outside of the partition wall 37 and the outside of the chamber 2a. Accordingly, the pressure in the second space 20b is maintained lower than the pressure in the first space 20a. As a result, the gas flows from the first space 20a toward the second space 20b at the EUV light passage port 371, the target passage port 374, and the laser light passage port 375. Therefore, the target substance is suppressed from moving from the second space 20b to the first space 20a, and debris of the target substance is suppressed from adhering to components such as the EUV light concentrating mirror 23b, the target supply unit 26, and the window 21.
2.3 Problem of Comparative Example

Many ions of the target substance emitted from the plasma generation region 25, gases, fine particles, and the like exist inside the partition wall 37. Some of such ions, gases, fine particles, and the like are deposited on the inner surface of the partition wall 37 as adhesion debris 27a of the target substance. As the deposition of the adhesion debris 27a progresses, the optical path of the pulse laser light 33 may be obstructed, or the gas flow inside the partition wall 37 may be changed to obstruct smooth evacuation.

The embodiments described below relate to melting and removing the adhesion debris 27a of the target substance deposited on the inner surface of the partition wall 37.

### 3. EUV Light Generation Apparatus 1b in Which Partition Wall 37b Includes Heater

3.1 Configuration

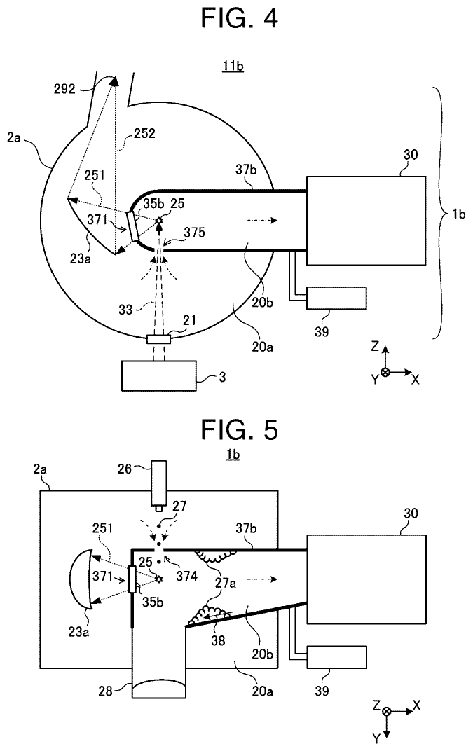

FIG. 4 shows the configuration of an EUV light generation system 11b according to a first embodiment, and FIG. 5 shows the configuration of an EUV light generation apparatus 1b shown in FIG. 4. FIG. 4 is a view of the EUV light generation system 11b viewed in the Y direction, and FIG. 5 is a view of the EUV light generation apparatus 1b viewed in the Z direction.

Instead of the partition wall 37 of the comparative example, a partition wall 37b including a heater is arranged in the first embodiment. A heater power source 39 is connected to the partition wall 37b. A temperature sensor (not shown) is arranged on the partition wall 37b, and the processor 5 (see FIG. 1) controls the heater power source 39 based on the output of the temperature sensor. The combination of the heater included in the partition wall 37b and the heater power source 39 is an example of the temperature adjuster in the present disclosure. The heater may be an electric heating wire or an induction heating coil.

A gate valve 35b is arranged at the EUV light passage port 371 of the partition wall 37b. The gate valve 35b is configured to be switchable between a first state in which the EUV light passage port 371 is opened and a second state in which the EUV light passage port 371 is sealed, and the switching operation is controlled by the processor 5. The gate valve 35b is an example of the first switch in the present disclosure.

The partition wall 37 of the comparative example has the substantially cylindrical shape having the center axis parallel to the X direction, whereas it is desirable that the center axis of the partition wall 37b is inclined downward from a connection portion with the exhaust device 30 toward a connection portion with the target collection unit 28. The partition wall 37b may be a tubular shape having a taper, and may be, for example, a part of a conical shape. Accordingly, a liquid flow path 38 inclined downward toward the connection portion with the target collection unit 28 is formed.
3.2 Operation

During a period in which the target 27 is supplied from the target supply unit 26 and the target 27 is irradiated with the pulse laser light 33 output from the laser device 3 to generate EUV light, the gate valve 35b causes the EUV light passage port 371 to be opened.

After EUV light is generated for a predetermined period, after a predetermined pulse number of EUV light is generated, after generation failure of EUV light, irradiation failure of the pulse laser light 33, or gas flow failure in the partition wall 37b is detected, or after the deposition of the adhesion debris 27a is detected by some sensor, the supplying of the target 27 and the irradiation with the pulse laser light 33 are stopped, and the EUV light passage port 371 is sealed by the gate valve 35b. Then, the heater power source 39 supplies a current to the heater to heat the partition wall 37b to a temperature equal to or higher than the melting point of the target substance, thereby melting the adhesion debris 27a. The molten adhesion debris 27a falls due to gravity or travels along the inner surface of the partition wall 37b, and is collected by the target collection unit 28.

The heating time of the partition wall 37b is preferably 1 hour or more and 5 hours or less, for example, about 3 hours. When the target substance contains tin, since the melting point of tin is about 232° C., it is desirable that the partition wall 37b is heated to a temperature in a range of 250° C. or higher and 350° C. or lower. When the target substance contains lithium, since the melting point of lithium is about 180° C., it is desirable that the partition wall 37b is heated to a temperature in a range of 200° C. or higher and 300° C. or lower.

Then, the heater power source 39 stops supplying the current, and after the temperature of the partition wall 37b becomes equal to or lower than the melting point of the target substance, the gate valve 35b is opened and generation of the EUV light is resumed. Thus, the partition wall 37b is heated while generation of the EUV light is stopped.
3.3 Effect

(1) According to the first embodiment, the EUV light generation apparatus 1b includes the chamber 2a, the partition wall 37b, the target supply unit 26, the EUV light concentrating mirror 23a, the target collection unit 28, the heater, the heater power source 39, and the first switch such as the gate valve 35b. The chamber 2a surrounds the first space 20a. The partition wall 37b surrounds the second space 20b and includes the EUV light passage port 371 that allows the first space 20a to communicate with the second space 20b. The target supply unit 26 supplies the target 27 containing the target substance to the plasma generation region 25 inside the second space 20b. The EUV light concentrating mirror 23a concentrates the EUV light generated in the plasma generation region 25. The target collection unit 28 collects the target 27 that has passed through the plasma generation region 25 and the adhesion debris 27a of the target substance that has adhered to the inner surface of the partition wall 37b. The heater and the heater power source 39 heats the partition wall 37b. The first switch switches opening and closing of the EUV light passage port 371.

According to this configuration, it is possible to melt the adhesion debris 27a on the inner surface of the partition wall by heating the partition wall 37b, and to move the molten adhesion debris 27a to the target collection unit 28 by gravity. As a result, it is possible to suppress the adhesion debris 27a on the inner surface of the partition wall 37b from obstructing the progress of the pulse laser light 33 and the gas flow. Further, when the molten adhesion debris 27a falls, splash of the target substance may scatter. However, by closing the EUV light passage port 371, it is possible to suppress contamination of the components arranged in the first space 20a. Further, the work load is less than that required for disassembling the EUV light generation apparatus 1b and manually removing the adhesion debris 27a.

(2) According to the first embodiment, the target collection unit 28 is connected to the partition wall 37b, and the partition wall 37b has a tubular shape in which the center axis is inclined toward the gravity direction as oriented toward the connection portion connected to the target collection unit 28.

According to this configuration, since the partition wall 37b is entirely inclined, the molten adhesion debris 27a can be efficiently guided to the target collection unit 28.

(3) According to the first embodiment, the target collection unit 28 is connected to the partition wall 37b, and the partition wall 37b includes the liquid flow path 38 which is inclined toward the gravity direction as oriented toward the connection portion connected to the target collection unit 28.

According to this configuration, the molten adhesion debris 27a can be smoothly guided to the target collection unit 28 via the liquid flow path 38.

(4) According to the first embodiment, the heater and the heater power source 39 heat the partition wall 37b for 1 hour or more and 5 hours or less.

According to this configuration, even when the viscosity of the molten adhesion debris 27a is high, it can be removed from the inner surface of the partition wall 37b over a sufficient time.

(5) According to the first embodiment, the target substance contains tin, and the heater and the heater power source 39 heat the partition wall 37b to a temperature in a range of 250° C. or higher and 350° C. or lower.

According to this configuration, the adhesion debris 27a can be removed by being heated to a temperature equal to or higher than the melting point of tin.

(6) According to the first embodiment, the target substance contains lithium, and the heater and the heater power source 39 heat the partition wall 37b to a temperature in a range of 200° C. or higher and 300° C. or lower.

According to this configuration, the adhesion debris 27a can be removed by being heated to a temperature equal to or higher than the melting point of lithium.

(7) According to the first embodiment, the heater and the heater power source 39 heats the partition wall 37b after the EUV light passage port 371 is closed.

According to this configuration, since the adhesion debris 27a is melted after the EUV light passage port 371 is closed, it is possible to suppress contamination of the components arranged in the first space 20a.

(8) According to the first embodiment, the EUV light passage port 371 is opened after heating of the partition wall 37b by the heater and the heater power source 39 is stopped and a temperature of the partition wall 37b becomes equal to or lower than the melting point of the target substance.

According to this configuration, even when a part of the adhesion debris 27a remains on the inner surface of the partition wall 37b after being heated, occurrence of splash can be suppressed by opening the EUV light passage port 371 after the adhesion debris 27a has reached a temperature equal to or lower than the melting point of the target substance.

(9) According to the first embodiment, the heater and the heater power source 39 heat the partition wall 37b while generation of the EUV light is stopped.

According to this configuration, even when there is a restriction on the operation of the heater power source 39 or the operation of the first switch during generation of the EUV light, the restriction is reduced by stopping generation of the EUV light, and the adhesion debris 27a can be smoothly removed.

(10) According to the first embodiment, the EUV light concentrating mirror 23a is located at a position inside the first space 20a and outside the second space 20b, and concentrates the EUV light that has passed through the EUV light passage port 371.

According to this configuration, when the EUV light passage port 371 is closed, adhesion of the target substance on the EUV light concentrating mirror 23a is suppressed, and a decrease in the reflectance of the EUV light concentrating mirror 23a is suppressed.

(11) According to the first embodiment, the first switch includes the gate valve 35b that seals the EUV light passage port 371.

According to this configuration, even when a part of the molten target substance is vaporized, it is possible to suppress the target substance from flowing into the first space 20a.

In other respects, the first embodiment is similar to the comparative example.

### 4. EUV Light Generation Apparatus 1c Including Shutter 35c Instead of Gate Valve 35b

4.1 Configuration and Operation

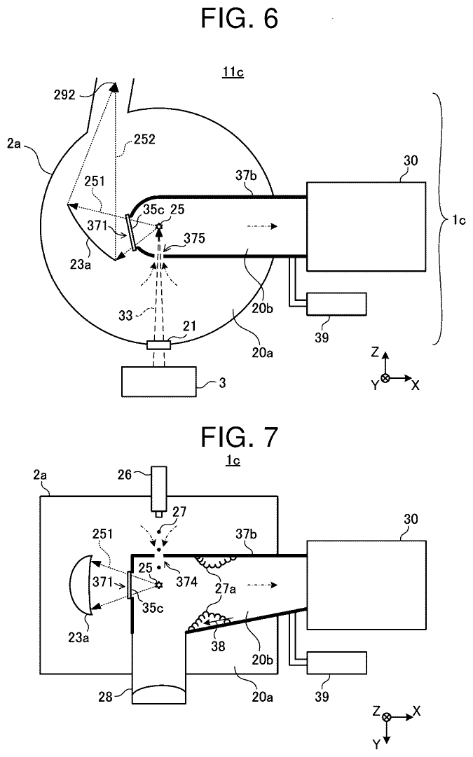

FIG. 6 shows the configuration of an EUV light generation system 11c according to a first modification of the first embodiment, and FIG. 7 shows the configuration of an EUV light generation apparatus 1c shown in FIG. 6. FIG. 6 is a view of the EUV light generation system 11c viewed in the Y direction, and FIG. 7 is a view of the EUV light generation apparatus 1c viewed in the Z direction.

Instead of the gate valve 35b in the first embodiment, a shutter 35c is arranged in the first modification. The shutter 35c does not perform sealing like the gate valve 35b, but may close the EUV light passage port 371 by being located in the vicinity of the EUV light passage opening 371 and open the EUV light passage port 371 by being retracted from the optical path of the radiation light passing through the EUV light passage port 371. The opening and closing mechanism of the shutter 35c may have a simple configuration using a motor (not shown) or a solenoid (not shown), and the shutter 35c may be opened and closed by translating in a direction intersecting the center axis of the optical path of the radiation light 251, or may be opened and closed by rotating about a rotation axis.
4.2 Effect

(12) According to the first modification, the first switch includes the shutter 35c arranged in the vicinity of the EUV light passage port 371.

According to this configuration, even when the first switch does not have a complicated configuration, the EUV light passage port 371 can be closed, and contamination of components in the first space 20a can be suppressed.

In other respects, the first modification is similar to the first embodiment.

### 5. EUV Light Generation Apparatus 1d in Which Gate Valve 35d Includes Heater

5.1 Configuration and Operation

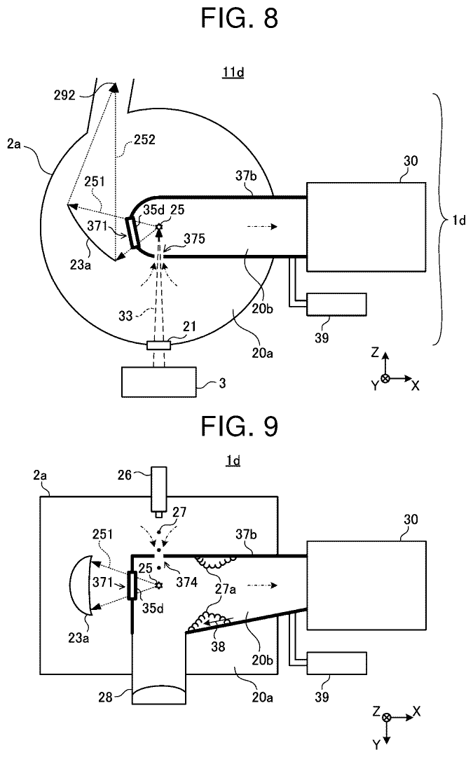

FIG. 8 shows the configuration of an EUV light generation system 11d according to a second modification of the first embodiment, and FIG. 9 shows the configuration of an EUV light generation apparatus 1d shown in FIG. 8. FIG. 8 is a view of the EUV light generation system 11d viewed in the Y direction, and FIG. 9 is a view of the EUV light generation apparatus 1d viewed in the Z direction.

Instead of the gate valve 35b in the first embodiment, a gate valve 35d including a heater is arranged in the second modification. The gate valve 35d is a heat resistant gate valve that withstands a temperature equal to or higher than the melting point of the target substance. The heater power source 39 is connected not only to the partition wall 37b but also to the gate valve 35d. The heater included in the partition wall 37b corresponds to the first heater in the present disclosure, the heater included in the gate valve 35d corresponds to the second heater in the present disclosure, and the combination of the first and second heaters and the heater power source 39 is an example of the temperature adjuster in the present disclosure. The timing of starting and ending heating of the gate valve 35d may be the same as that of the partition wall 37b.
5.2 Effect

(13) According to the second modification, the heater includes the first heater for heating the partition wall 37b and the second heater for heating the first switch such as the gate valve 35d.

According to this configuration, by heating not only the partition wall 37b but also the first switch, it is possible to suppress the target substance from adhering to the first switch and the inability to perform opening and closing operation.

In other respects, the second modification is similar to the first embodiment. Alternatively, the shutter 35c in the first modification may include a heater.

### 6. EUV Light Generation Apparatus 1e in Which Gate Valve 36e is Arranged at Target Passage Port 373

6.1 Configuration and Operation

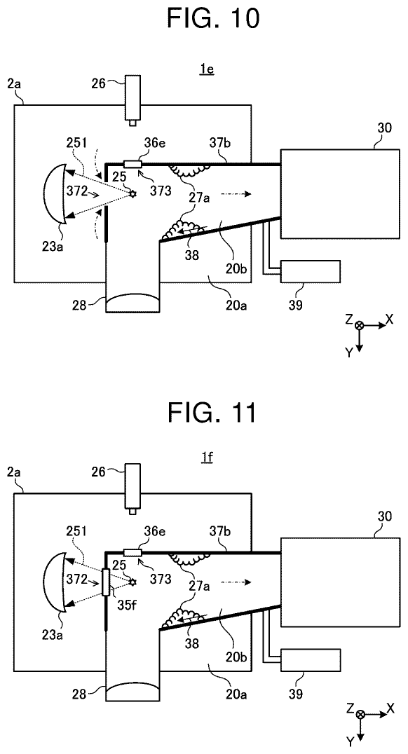

FIG. 10 shows the configuration of an EUV light generation apparatus 1e according to a second embodiment. FIG. 10 is a view of the EUV light generation apparatus 1e viewed in the Z direction. In the first embodiment, the gate valve 35b is arranged at the EUV light passage port 371, whereas in the second embodiment, a gate valve 36e is arranged at the target passage port 373. The gate valve 36e is configured to be switchable between a first state in which the target passage port 373 is opened and a second state in which the target passage port 373 is sealed, and the switching operation is controlled by the processor 5. The target passage port 373 is an example of the first opening in the present disclosure, and the configuration thereof is similar to that of the target passage port 374. The gate valve 36e is an example of the first switch in the present disclosure. The timing of opening and closing the gate valve 36e may be similar to that of the gate valve 35b. The EUV light passage port 372 corresponds to the second opening in the present disclosure, and the configuration thereof is similar to that of the EUV light passage port 371. The gate valve 35b may not be arranged at the EUV light passage port 372.
6.2 Effect

(14) According to the second embodiment, the target supply unit 26 is located outside the second space 20b, and supplies the target 27 to the plasma generation region 25 via the target passage port 373.

According to this configuration, when the target passage port 373 is closed, adhesion of the target substance on the target supply unit 26 is suppressed, and a change in the trajectory of the target 27 is suppressed.

(15) According to the second embodiment, the first switch includes the gate valve 36e that seals the target passage port 373.

According to this configuration, even when a part of the molten target substance is vaporized, it is possible to suppress the target substance from flowing into the first space 20a.

(16) According to the second embodiment, as will be described later, the first switch includes a shutter arranged in the vicinity of the target passage port 373.

According to this configuration, even when the first switch does not have a complicated configuration, the target passage port 373 can be closed, and contamination of components in the first space 20a can be suppressed.

(17) According to the second embodiment, as will be described later, the heater includes the first heater that heats the partition wall 37b and the second heater that heats the first switch such as the gate valve 36e and the shutter.

According to this configuration, by heating not only the partition wall 37b but also the first switch, it is possible to suppress the target substance from adhering to the first switch and the inability to perform opening and closing operation.

In other respects, the second embodiment is similar to the first embodiment. Alternatively, similarly to the first modification, a shutter may be arranged in the vicinity of the target passage port 373 instead of the gate valve 36e, and similarly to the second modification, the gate valve 36e may include a heater or the shutter may include a heater.

7. EUV light generation apparatus 1f in which gate valve 36e is arranged at target passage port 373 and gate valve 35f is arranged at EUV light passage port 372
7.1 Configuration and Operation

FIG. 11 shows the configuration of an EUV light generation apparatus 1f according to a third embodiment. FIG. 11 is a view of the EUV light generation apparatus 1f viewed in the Z direction. In the third embodiment, the gate valve 35f is also arranged at the EUV light passage port 372. The gate valve 35f is configured to be switchable between a first state in which the EUV light passage port 372 is opened and a second state in which the EUV light passage port 372 is sealed, and the switching operation is controlled by the processor 5. The gate valve 35f corresponds to the second switch in the present disclosure. The timing of opening and closing the gate valve 35f may be similar to that of the gate valve 36e.
7.2 Effect

(18) According to the third embodiment, the partition wall 37b includes the EUV light passage port 372 that allows the first space 20a to communicate with the second space 20b. The EUV light concentrating mirror 23a is located at a position inside the first space 20a and outside the second space 20b, and concentrates the EUV light that has passed through the EUV light passage port 372. The EUV light generation apparatus 1f includes the second switch such as the gate valve 35f for switching opening and closing of the EUV light passage port 372.

According to this configuration, contamination of both the target supply unit 26 and the EUV light concentrating mirror 23a can be suppressed.

In other respects, the third embodiment is similar to the second embodiment. Alternatively, similarly to the first modification, a shutter may be arranged instead of the gate valve 36e or the gate valve 35f, and similarly to the second modification, the gate valve 36e or the gate valve 35f may include a heater or the shutter may include a heater.

In any one of the first to third embodiments and the first and second modifications, a gate valve or a shutter may be arranged at the laser light passage port 375 or a through hole for a sensor, and the gate valve or the shutter may include a heater.

### 8. Others

8.1 Example of EUV Light Utilization Apparatus 6

FIG. 12 shows the configuration of the exposure apparatus 6a connected to the EUV light generation system 11b. In FIG. 12, the exposure apparatus 6a as the EUV light utilization apparatus 6 (see FIG. 1) includes a mask irradiation unit 608 and a workpiece irradiation unit 609. The mask irradiation unit 608 illuminates, via a reflection optical system, a mask pattern of a mask table MT with the EUV light incident from the EUV light generation system 11b. The workpiece irradiation unit 609 images the EUV light reflected by the mask table MT onto a workpiece (not shown) arranged on a workpiece table WT via the reflection optical system. The workpiece is a photosensitive substrate such as a semiconductor wafer on which photoresist is applied. The exposure apparatus 6a synchronously translates the mask table MT and the workpiece table WT to expose the workpiece to the EUV light reflecting the mask pattern. Through the exposure process as described above, a device pattern is transferred onto the semiconductor wafer, thereby an electronic device can be manufactured.

FIG. 13 shows the configuration of the inspection apparatus 6b connected to the EUV light generation system 11b. In FIG. 13, the inspection apparatus 6b as the EUV light utilization apparatus 6 (see FIG. 1) includes an illumination optical system 603 and a detection optical system 606. The illumination optical system 603 reflects the EUV light incident from the EUV light generation system 11b to illuminate a mask 605 placed on a mask stage 604. Here, the mask 605 conceptually includes a mask blanks before a pattern is formed. The detection optical system 606 reflects the EUV light from the illuminated mask 605 and forms an image on a light receiving surface of a detector 607. The detector 607 having received the EUV light obtains the image of the mask 605. The detector 607 is, for example, a time delay integration (TDI) camera. Inspection for a defect of the mask 605 is performed based on the image of the mask 605 obtained by the above-described steps, and a mask suitable for manufacturing an electronic device is selected using the inspection result. Then, the electronic device can be manufactured by exposing and transferring the pattern formed on the selected mask onto the photosensitive substrate using the exposure apparatus 6a.

Although FIGS. 12 and 13 show the EUV light generation system 11b according to the first embodiment, the EUV light generation system 11c or 11d according to the first or second modification may be used, or an EUV light generation system including the EUV light generation apparatus 1e or 1f according to the second or third embodiment may be used.
8.2 Supplement

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of the any thereof and any other than A, B, and C.

What is claimed is:

1. An extreme ultraviolet light generation apparatus comprising:
a chamber surrounding a first space;
a partition wall surrounding a second space and including a first opening allowing the first space to communicate with the second space;
a target supply unit configured to supply a target including a target substance to a plasma generation region in the second space;
an EUV light concentrating mirror configured to concentrate extreme ultraviolet light generated in the plasma generation region;
a target collection unit configured to collect the target that has passed through the plasma generation region and adhesion debris of the target substance that has adhered to an inner surface of the partition wall;
a temperature adjuster configured to heat the partition wall; and
a first switch configured to switch opening and closing of the first opening.

2. The extreme ultraviolet light generation apparatus according to claim 1,
wherein the target collection unit is connected to the partition wall, and
the partition wall has a tubular shape in which a center axis thereof is inclined toward the gravity direction as oriented toward a connection portion connected to the target collection unit.

3. The extreme ultraviolet light generation apparatus according to claim 1,
wherein the target collection unit is connected to the partition wall, and
the partition wall includes a liquid flow path inclined toward the gravity direction as oriented toward a connection portion connected to the target collection unit.

4. The extreme ultraviolet light generation apparatus according to claim 1,
wherein the temperature adjuster heats the partition wall for 1 hour or more and 5 hours or less.

5. The extreme ultraviolet light generation apparatus according to claim 1,
wherein the target substance contains tin, and
the temperature adjuster heats the partition wall to a temperature in a range of 250° C. or higher and 350° C. or lower.

6. The extreme ultraviolet light generation apparatus according to claim 1,
wherein the target substance contains lithium, and
the temperature adjuster heats the partition wall to a temperature in a range of 200° C. or higher and 300° C. or lower.

7. The extreme ultraviolet light generation apparatus according to claim 1,
wherein the temperature adjuster heats the partition wall after the first opening is closed.

8. The extreme ultraviolet light generation apparatus according to claim 1,
wherein the first opening is opened after heating of the partition wall by the temperature adjuster is stopped and a temperature of the partition wall becomes equal to or lower than a melting point of the target substance.

9. The extreme ultraviolet light generation apparatus according to claim 1,
wherein the temperature adjuster heats the partition wall while generation of the extreme ultraviolet light is stopped.

10. The extreme ultraviolet light generation apparatus according to claim 1,
wherein the EUV light concentrating mirror is located at a position inside the first space and outside the second space, and concentrates the extreme ultraviolet light that has passed through the first opening.

11. The extreme ultraviolet light generation apparatus according to claim 10,
wherein the first switch includes a gate valve that seals the first opening.

12. The extreme ultraviolet light generation apparatus according to claim 10,
wherein the first switch includes a shutter arranged in the vicinity of the first opening.

13. The extreme ultraviolet light generation apparatus according to claim 10,
wherein the temperature adjuster includes a first heater for heating the partition wall and a second heater for heating the first switch.

14. The extreme ultraviolet light generation apparatus according to claim 1,
wherein the target supply unit is located outside the second space, and supplies the target to the plasma generation region via the first opening.

15. The extreme ultraviolet light generation apparatus according to claim 14,
wherein the first switch includes a gate valve that seals the first opening.

16. The extreme ultraviolet light generation apparatus according to claim 14,
wherein the first switch includes a shutter arranged in the vicinity of the first opening.

17. The extreme ultraviolet light generation apparatus according to claim 14,
wherein the temperature adjuster includes a first heater for heating the partition wall and a second heater for heating the first switch.

18. The extreme ultraviolet light generation apparatus according to claim 14, further comprising
a second switch configured to switch opening and closing of a second opening formed at the partition wall and allowing a first space to communicate with the second space,
wherein the EUV light concentrating mirror is located at a position inside the first space and outside the second space, and concentrates the extreme ultraviolet light that has passed through the second opening.

19. An electronic device manufacturing method, comprising:
generating extreme ultraviolet light using an extreme ultraviolet light generation apparatus;
outputting the extreme ultraviolet light to an exposure apparatus; and
exposing a photosensitive substrate to the extreme ultraviolet light in the exposure apparatus to manufacture an electronic device,
the extreme ultraviolet light generation apparatus including:
a chamber surrounding a first space;
a partition wall surrounding a second space and including a first opening allowing the first space to communicate with the second space;
a target supply unit configured to supply a target including a target substance to a plasma generation region in the second space;
an EUV light concentrating mirror configured to concentrate the extreme ultraviolet light generated in the plasma generation region;
a target collection unit configured to collect the target that has passed through the plasma generation region and adhesion debris of the target substance that has adhered to an inner surface of the partition wall;
a temperature adjuster configured to heat the partition wall; and
a first switch configured to switch opening and closing of the first opening.

20. An electronic device manufacturing method, comprising:
inspecting a defect of a mask by irradiating the mask in an inspection apparatus with extreme ultraviolet light generated by an extreme ultraviolet light generation apparatus;
selecting a mask using a result of the inspection; and
exposing and transferring a pattern formed on the selected mask onto a photosensitive substrate,
the extreme ultraviolet light generation apparatus including:
a chamber surrounding a first space;
a partition wall surrounding a second space and including a first opening allowing the first space to communicate with the second space;
a target supply unit configured to supply a target including a target substance to a plasma generation region in the second space;
an EUV light concentrating mirror configured to concentrate the extreme ultraviolet light generated in the plasma generation region;
a target collection unit configured to collect the target that has passed through the plasma generation region and adhesion debris of the target substance that has adhered to an inner surface of the partition wall;
a temperature adjuster configured to heat the partition wall; and
a first switch configured to switch opening and closing of the first opening.
